(19) United States
(12) Patent Application Publication
(10) Pub. No.: US 2026/0303021 A1
(43) Pub. Date: Oct. 1, 2026

(54) AMPLIFIER CIRCUIT

(71) Applicant: BAE Systems Information and Electronic Systems Integration Inc., Nashua, NH (US)

(72) Inventor: Gary M. Madison, Jr., Waltham, MA (US)

(73) Assignee: BAE Systems Information and Electronic Systems Integration Inc., Nashua, NH (US)

(21) Appl. No.: 19/095,223

(22) Filed: Mar. 31, 2025

(51) Int. Cl. H03F 1/02; H03F 3/45

(52) U.S. Cl. CPC H03F 1/0205; H03F 3/45269; H03F 2200/129

(57) ABSTRACT

An amplifier circuit capable of achieving low power consumption, high speed performance, linearity, and capacity to drive high capacitive loads includes a first operational transconductance amplifier coupled to a first input, and a second operational transconductance amplifier coupled to a second input. The amplifier circuit further includes a first current mirror circuit coupled to the first and second operational transconductance amplifiers, and a second current mirror circuit coupled to the first and second operational transconductance amplifiers. A plurality of resistors in series is coupled to the first and second operational transconductance amplifiers, and further coupled to the first and second current mirrors. A first amplifier output is coupled between the first and second current mirrors, and a second amplifier output is coupled between the first and second current mirrors.

### STATEMENT OF GOVERMENT INTEREST

This invention was made with government support under contract FA8650-23-C-7304 with the Department of Defense. The government has certain rights in the invention.

### FIELD OF DISCLOSURE

The present disclosure relates to electronic circuitry, and more particularly, to techniques for amplifying signals.

### BACKGROUND

An operational amplifier (op-amp) is a type of electrical circuit that amplifies the difference between two inputs. Op-amps are used in a large variety of analog electronics applications. However, when the load on the output of a given op-amp is largely capacitive, some op-amps may experience undesirable peaking and oscillation, or other issues such as high-power consumption and non-linear performance. Therefore, non-trivial issues are present with existing amplifier designs.

### SUMMARY

The present disclosure relates to techniques for signal amplification, particularly in the context of low power consumption, high speed performance, linearity, and capacity to drive high capacitive loads. An amplifier circuit is described that includes a first operational transconductance amplifier (OTA) coupled to a first input, and a second OTA coupled to a second input. The amplifier circuit further includes a first current mirror circuit coupled to the first and second OTAs, and a second current mirror circuit coupled to the first and second OTAs. A plurality of resistors in series is coupled to the first and second OTAs, and further coupled to the first and second current mirrors. The amplifier circuit is capable of achieving low power consumption, high speed performance, linearity, and capacity to drive high capacitive loads, while maintaining a high input impedance and a high output impedance when switched off.

The amplifier circuit operates in class AB, drawing higher current only while slewing, with feedback to maintain linearity. The circuit includes a bias current source that sources current into a center tap of the tapped resistor series, allowing for control of the output common-mode voltage independently of the differential voltage. The amplifier circuit also includes switches for switching the amplifier outputs on and off, and an enable circuit for isolating the amplifier circuit from a power supply.

Various examples of the amplifier circuit are described, including different configurations of the OTAs, current mirror circuits, and resistors. The amplifier circuit is suitable for use in a variety of applications, including integrated circuits, imaging, radar, and radio communications.

The features and advantages described herein are not all-inclusive and, in particular, additional features and advantages will be apparent to one of ordinary skill in the art in view of the drawings, specification, and claims. Moreover, it should be noted that the language used in the specification has been selected principally for readability and instructional purposes, and not to limit the scope of the disclosed subject matter.

### BRIEF DESCRIPTION OF THE DRAWINGS

FIG. 1 is a block diagram of a system including a capacitive load and an amplifier/buffer, in accordance with an example of the present disclosure.

FIG. 2 is a block diagram of the amplifier/buffer of FIG. 1 in further detail, in accordance with an example of the present disclosure.

FIG. 3 is a schematic diagram of the amplifier/buffer of FIG. 2, in accordance with an example of the present disclosure.

FIG. 4 is a schematic diagram of a bias current source of FIGS. 2 and 3, in accordance with an example of the present disclosure.

FIG. 5 is a schematic diagram of a first operational transconductance amplifier of FIGS. 2 and 3, in accordance with an example of the present disclosure.

FIG. 6 is a schematic diagram of a first differential current mirror circuit, a second differential current mirror circuit, and a tapped resistor series of FIGS. 2 and 3, in accordance with an example of the present disclosure.

Although the following detailed description refers to illustrative examples, many alternatives, modifications, and variations thereof will be apparent in light of this disclosure.

### DETAILED DESCRIPTION

Techniques are provided herein for signal amplification. In accordance with an example of the present disclosure, an amplifier circuit is capable of achieving low power consumption, high speed performance, linearity, and capacity to drive high capacitive loads. The amplifier circuit includes a first operational transconductance amplifier coupled to a first input, and a second operational transconductance amplifier coupled to a second input. The amplifier circuit further includes a first current mirror circuit coupled to the first and second operational transconductance amplifiers, and a second current mirror circuit coupled to the first and second operational transconductance amplifiers. A plurality of resistors in series is coupled to the first and second operational transconductance amplifiers, and further coupled to the first and second current mirrors. A first output is coupled between the first and second current mirrors, and a second output is coupled between the first and second current mirrors. Numerous variations will be apparent in light of this disclosure.

The performance of a given amplifier can be defined by various properties, such as power consumption, speed, linearity, and capacity to drive high capacitive loads. Often, existing amplifier designs sacrifice one or more of these properties to achieve other goals. For example, performance, linearity, and capacity of a standard complementary metal oxide semiconductor (CMOS) amplifier may be achieved at the cost of higher power consumption. Likewise, reducing power consumption may adversely affect the ability of the CMOS amplifier to operate at high speed, achieve linear performance, and/or drive high capacitive loads. Therefore, there remain non-trivial issues regarding CMOS amplifier design, including achieving high speed, linear performance with low power consumption while also driving high capacitive loads.

To this end, and in accordance with an example of the present disclosure, a CMOS amplifier is capable of achieving low power consumption, high speed performance, linearity, and capacity to drive high capacitive loads. Additionally, the CMOS amplifier maintains a high input impedance and a high output impedance when switched off. For example, while running on a 1.0V supply drawing 28-35uA, quiescent, the CMOS amplifier can provide ≈14dB of gain while delivering up to 1.0V peak-to-peak differential output into a dual 400fF differential load, with settling to less than or equal to 48dB below full output in less than or equal to 3.2ns. By operating in class AB, the CMOS amplifier draws higher current only while slewing, with feedback to maintain linearity. While examples described herein are provided with CMOS technology, other amplifier types may also benefit from the techniques described herein.

### Amplifier Architecture

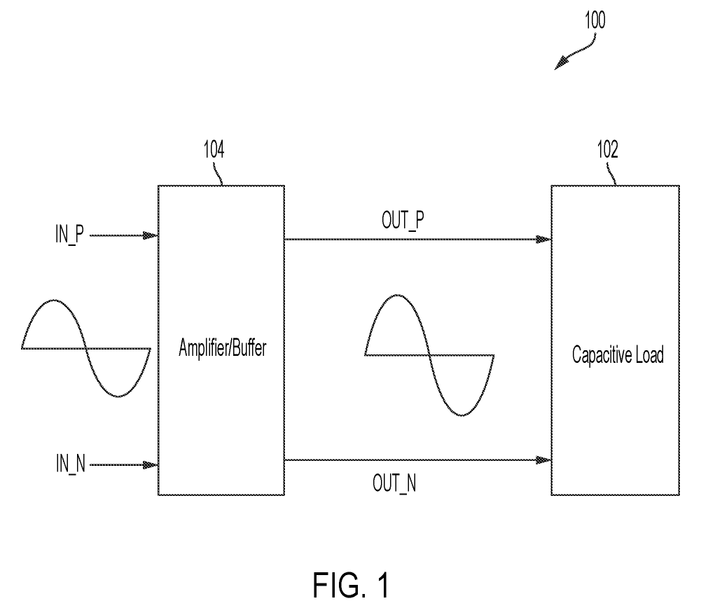

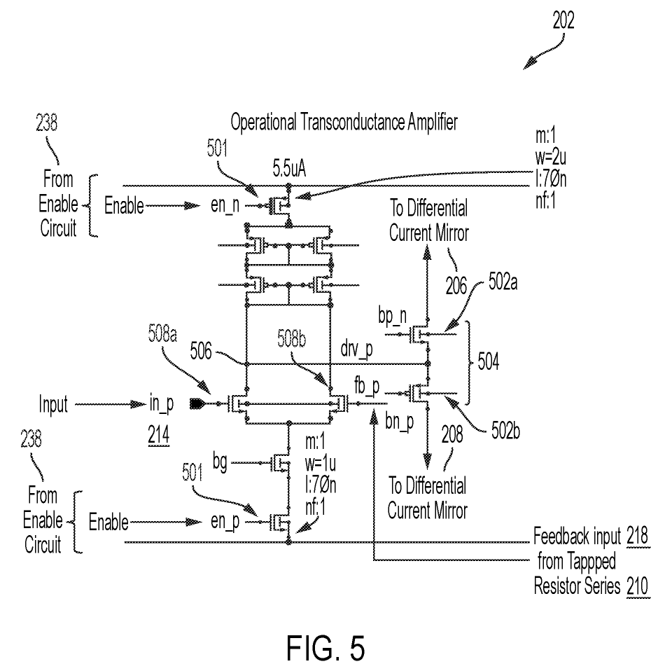

FIG. 1 is a block diagram of a system 100 including a capacitive load 102 and an amplifier/buffer 104, in accordance with an example of the present disclosure. In some examples, the system 100 is part of an integrated circuit, such as a CMOS-based integrated circuit. The capacitive load 102 can include capacitors or other capacitive devices that store energy for applications such as imaging, radar, and radio communications, particularly in small form factors such as integrated circuits. The amplifier/buffer 104 includes a class AB amplifier and additional circuitry, such as described in further detail below. As discussed in further detail below, the amplifier/buffer 104 includes two operational transconductance amplifiers (OTAs). Each OTA drives the sources of an n-type field-effect transistor (NFET) and a p-type field-effect transistor (PFET) (see FETS 504 in FIG. 5). In turn, each FET of each NFET-PFET pair conducts for slightly more than 180 degrees of the cycle of an input signal. The differential outputs of the amplifier/buffer 104, OUT_P and OUT_N, correspond to the amplified or buffered input signal, IN_P and IN_N. As described below, the amplifier/buffer 104 further includes a bias current source and two different current mirror circuits. For example, the output stages of the amplifier/buffer 104 are high-impedance current sources in which increased load capacitance improves stability. This is in contrast with standard op-amps that have emitter or source follower outputs to achieve a low output impedance, in which increased output capacitance can degrade stability.

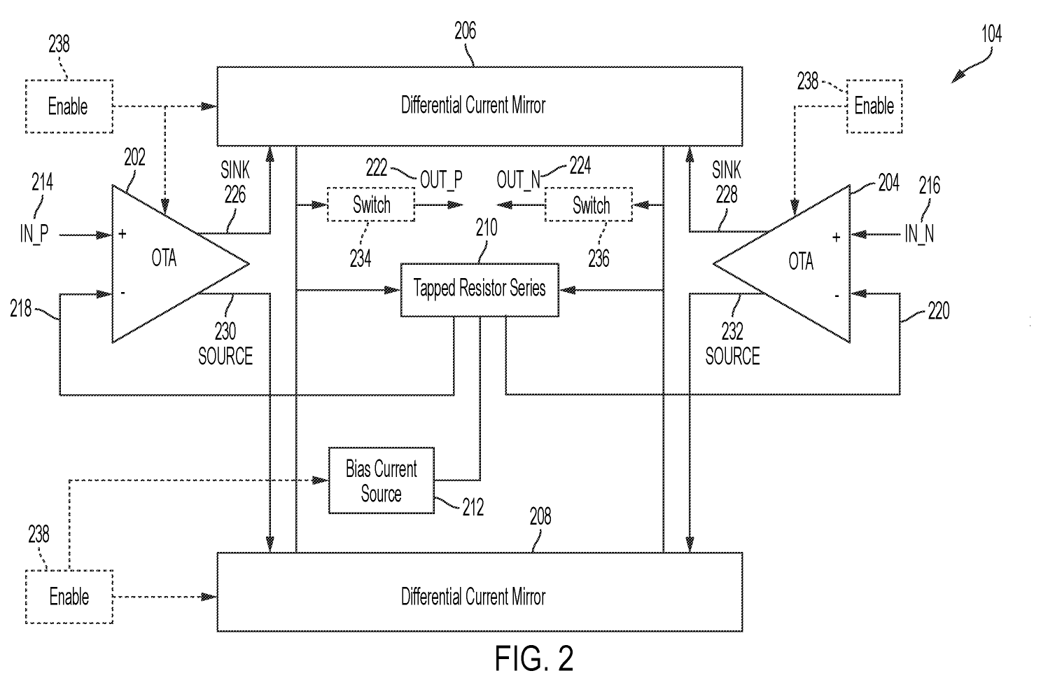

FIG. 2 is a block diagram of the amplifier/buffer 104 of FIG. 1 in further detail, in accordance with an example of the present disclosure. The amplifier/buffer 104 includes a first OTA 202, a second OTA 204 a first differential current mirror circuit 206, a second differential current mirror circuit 208, a tapped resistor series 210, and a bias current source 212.

The first OTA 202 is coupled to a first input 214 (e.g., a non-inverting input) and the second OTA 204 is coupled to a second input 216 (e.g., a non-inverting input). The first input 214 and the second input 216 are configured to receive input signals IN_P and IN_N, as well as feedback inputs 218 and 220 from the tapped resistor series 210 for providing signal linearity at amplifier outputs 222 and 224.

The first differential current mirror circuit 206 is coupled to a sinking output 226 of the first OTA 202 and a sinking output 228 of the second OTA 204. The second differential current mirror circuit 208 is coupled to a sourcing output 230 of the first OTA 202 and a sourcing output 232 of the second OTA 204. The corresponding outputs of the first OTA 202 (sinking output 226 and sourcing output 230) and the second OTA 204 (the sinking output 228 and the sourcing output 232) are differential (e.g., the voltage difference between the outputs of each amplifier). Any common mode voltage remaining is further attenuated by the differential current mirror circuits 206 and 208. The fixed, desired common-mode output voltage can be controlled independently of the differential voltage.

The tapped resistor series 210 is coupled to the feedback input 218 (e.g. an inverting input) of the first OTA 202, and to the feedback input 220 (e.g., an inverting input) of the second OTA 204. The tapped resistor series 210 is further coupled to the first differential current mirror circuit 206, the second differential current mirror circuit 208, and the bias current source 212. In some examples, the amplifier/buffer 104 has a nominal differential gain of 14dB, which is set by the resistors in the tapped resistor series 210.

The amplifier outputs 222 and 224 are each coupled to the first differential current mirror circuit 206 and the second differential current mirror circuit 208. In some examples, the amplifier/buffer 104 further includes switches 234 and 236 for switching the amplifier outputs 222 and 224. The switches 234 and 236 can be used, for example, to shut off the outputs 224 and 224 of the amplifier/buffer 104 quickly and to prevent unintended discharge of the load capacitance (e.g., for maintaining a fixed output voltage). Also, the amplifier outputs 222 and 224 provide a current source that maintains amplifier/buffer stability when coupled to large, capacitive loads, as opposed to some op-amp designs that become unstable when coupled to a large capacitive load.

The bias current source 212, which is coupled to the tapped resistor series 210, generates a DC current. The bias current source 212 is adjustable for setting the quiescent or common mode output voltage of the amplifier/buffer 104 (nominally 500mV in a 1V circuit) to a range of output voltages with peaks within 50mV of the supply rails.

In operation, when the amplifier/buffer 104 is operating at DC (e.g., no signals input, or input signals are absent), all voltages in the first differential current mirror circuit 206 and the second differential current mirror circuit 208 remain constant. An advantage of this design is that the amplifier/buffer 104 can be nominally operated with a low quiescent current (e.g., 15 µA). When an input signal with a sharp edge is applied, the first differential current mirror circuit 206 and the second differential current mirror circuit 208 draw a large current (e.g., milliamps of current) for charging the capacitive load until the output of the amplifier/buffer OUT_P and OUT_N settle, at which time the current drops back to quiescent. For example, an increase of the IN_P – IN_N voltage causes OTA 202 to sink current at the sinking output 226 and OTA 204 to the sourcing output 232, which causes current mirror circuit 208 to sink current from OUT_N and current mirror circuit 206 to source current into OUT_P. This delivers significant current to the capacitive load 102, causing voltage OUT_P – OUT_N to increase. This increase also occurs across the tapped resistor series 210, causing OTA 202 inverting input voltage to increase and OTA 204 inverting input voltage to decrease, until the inverting input voltage equals the non-inverting input on both OTA 202 and OTA 204. At this point all voltage slewing ends with currents back to their quiescent values.

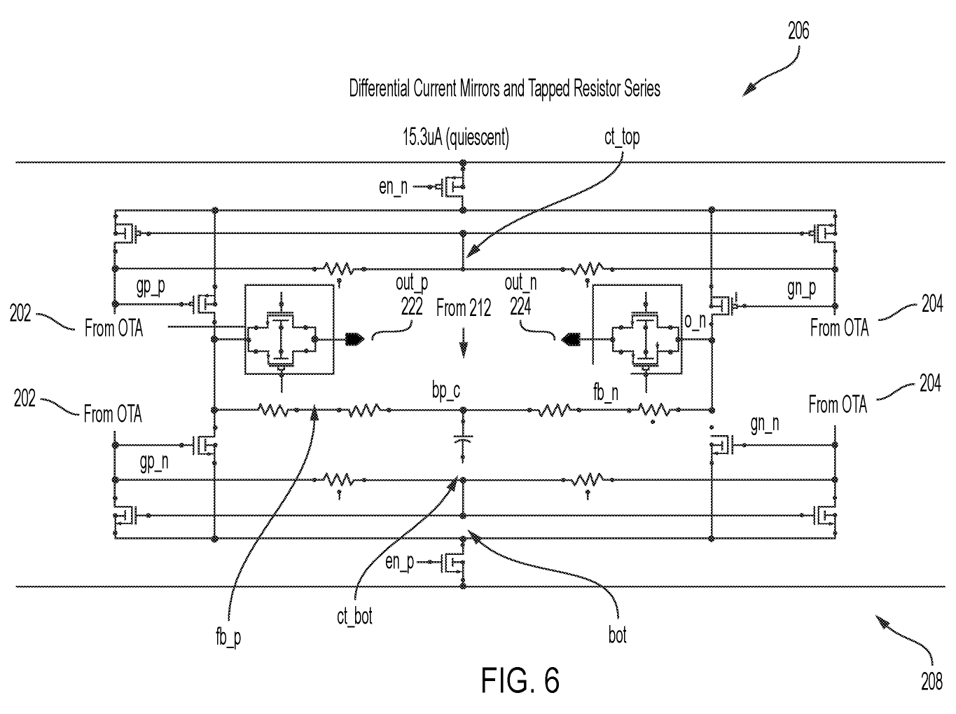

The bias current source 212 sources current into a center tap (bp_c) of the tapped resistor series 210 (see FIG. 6), thereby having an equal effect on both sides. If this bias current increases (with IN_P and IN_N voltage kept constant), OTA 202 will (through the differential current mirror circuits 206 and 208) keep fb_p equal to IN_P and OTA 204 will (through current mirrors) keep fb_n equal to IN_N. To achieve this, both OUT_P and OUT_N each move lower in voltage by the same amount; that is, OUT_P - OUT_N will not change. Thus, the effect of changing the bias current source 212 is to move the DC quiescent operating point up or down, accordingly.

As noted above, the quiescent currents of the first OTA 202 and the second OTA 204 and first differential current mirror circuit 206 and the second differential current mirror circuit 208 are very low (e.g., approximately 28-35uA). These circuits are designed to operate in class AB, in which signals applied to the inputs 214 and 216 (IN_P and IN_N) generate much larger currents within and from the amplifier/buffer 104. When the load is purely capacitive, these high currents are maintained only during sharp transitions of the input signal. When the output of the amplifier/buffer 104 reaches its final state, no more output current is called for, and the amplifier currents return to their quiescent levels. While the transition can be highly nonlinear, the amplifier/buffer 104 only has high currents during fast level transitions. In this manner, output signal linearity is maintained by the amplifier feedback for slow transitions and steady-state operation.

The final stages of the amplifier/buffer 104, including the first differential current mirror circuit 206 and the second differential current mirror circuit 208, are high-impedance current sources in which increased load capacitance improves stability. That is, the output load capacitance is effectively the dominant pole. This is in contrast with other op-amps that have emitter or source follower outputs to achieve a low output impedance, in which increased output capacitance usually degrades stability.

In some examples, the amplifier/buffer 104 includes an enable circuit 238. The enable circuit 238 can isolate each of the various components of the amplifier/buffer 104 from a power supply, effectively turning the amplifier/buffer 104 on and off according to the state of the enable circuit 238.

### Schematic

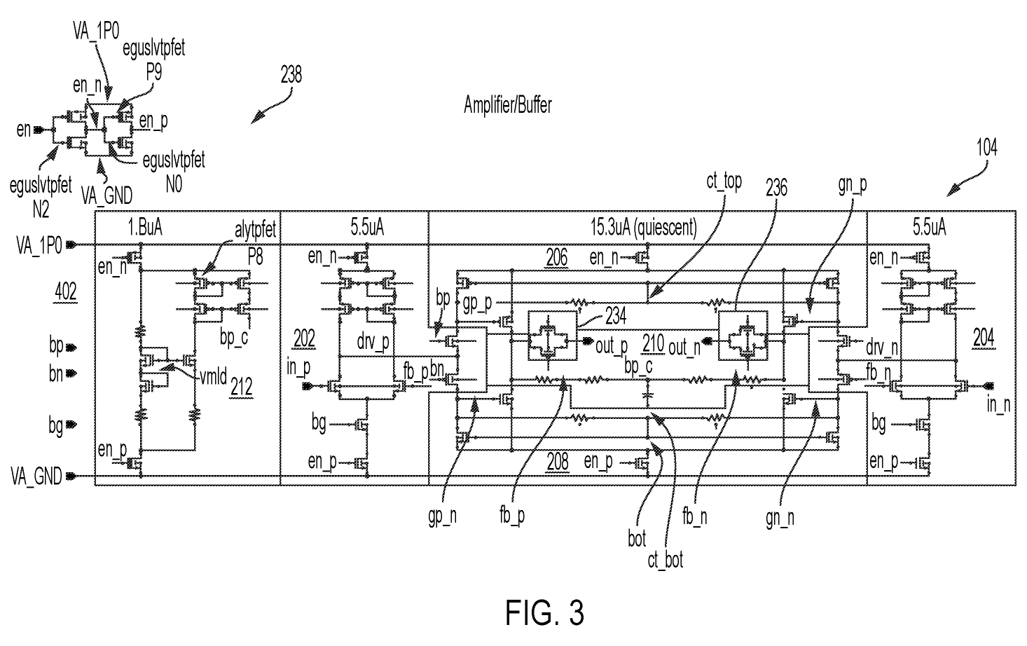

FIG. 3 is a schematic diagram of the amplifier/buffer 104, in accordance with an example of the present disclosure. FIG. 3 schematically depicts various components of the amplifier/buffer 104 including the first OTA 202, the second OTA 204, the first differential current mirror circuit 206, the second differential current mirror circuit 208, the tapped resistor series 210, the bias current source 212, the switches 234 and 236, and the enable circuit 238. The first OTA 202 and the second OTA 204, together with current mirror circuits 206 and 208, form class AB differential amplifiers for the inputs 214 and 216. These, together with outputs 222 and 224, are configured to be coupled to a high capacitive load. As noted above, some existing amplifier designs suffer from instability when coupled to high capacitive loads, or require high power for operation. In contrast to such existing designs, the OTA 202 and the OTA 204, in conjunction with the first and second differential current mirror circuits 206 and 208, permit the amplifier/buffer 104 to operate at a low quiescent voltage and current while driving a high capacitive load. Additionally, the output common-mode voltage can be controlled independently of the differential voltage by varying a bias current sourced from the bias current source 212. This provides operating point and common-mode voltage selection flexibility without sacrificing stable operation at DC or very low power consumption. Furthermore, after signal transitions, the circuit returns to stable, low power operation rapidly after the capacitive load has been charged. In some examples, the switches 234 and 236 are used to decouple the amplifier/buffer 104 from the load after charging to prevent or otherwise limit discharge of the load back through the amplifier.

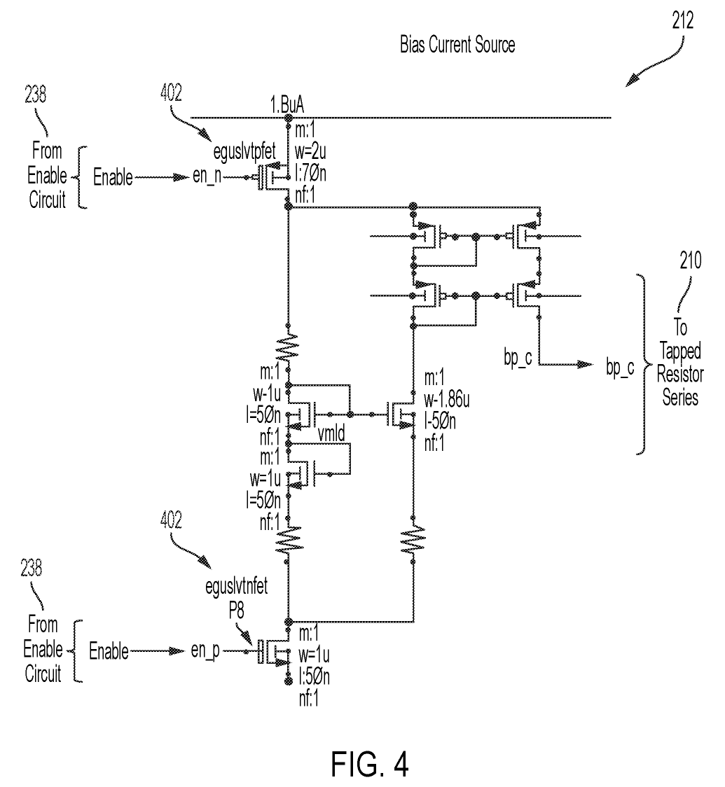

FIG. 4 is a schematic diagram of the bias current source 212 of FIG. 3, in accordance with an example of the present disclosure. The bias current source 212 generates a DC current (bp_c) for setting the quiescent output voltage of the amplifier/buffer 104 within a range of voltages (e.g., between 0 and 1 V). The DC current (bp_c) is applied to the center of the tapped resistor series 210, such as shown in FIG. 6, to pull the output common-mode voltage of the amplifier/buffer 104 down, or by reducing current, allowing it to rise. The bias current source 212 includes enable switches 402, controlled by an enable signal from the enable circuit 238, for turning the bias current source 212 on and off.

FIG. 5 is a schematic diagram of the first OTA 202, in accordance with an example of the present disclosure. (The second OTA 204 is similar for the negative side of the amplifier/buffer 104.) An operational transconductance amplifier is an amplifier that outputs a current proportional to the input voltage (that is, the output current of the amplifier is controlled by the input voltage). The first OTA 202 and the second OTA 204 are each differential, with one input (e.g., the input 214) controlling the gate of one FET 508a, and another input (e.g., a voltage from the tapped resistor series 210) controlling the gate of the other FET 508b. The differential voltages from the pre-switched amplifier/buffer 104 applied across the tapped resistor series 210, and from taps fb_p and fb_n to gates 218 and 220 of OTAs 202 and 204, respectively, represent feedback necessary for maintaining a linear response. The bias current source is applied specifically to the center tap of the tapped resistor bp_c. The taps fb_p and fb_n, which are equally spaced about the center tap bp_c, are applied differentially to the two OTAs 202 and 204. DC bias voltages are provided to the gates of the FETs 504 such that bp is applied to the gate of the NFET 502a and bn applied to the PFET 502b, as bp > bn in normal operation, with both FETs in common gate mode. In this manner, quiescent current in both FETs is about equal and just high enough to maintain the desired speed and frequency response of the amplifier/buffer 104. In OTA 202, the drv_p signal 506 feeds the sources of the NFET-PFET pair, with the sinking output 226 of the NFET 502a sinking current from the differential current mirror circuit 206 and the sourcing output 230 of the PFET 502b sourcing current to the differential current mirror circuit 208. In OTA 204, the drv_n signal feeds the sources of the NFET-PFET pair, with the sinking output 228 of the NFET sinking current from differential current mirror circuit 206 and the sourcing output 232 of the PFET sourcing current to differential current mirror circuit 208. The first OTA 202 and the second OTA 204 each include a current source NFET with gate bias supplied by signal bg and enable switches 501, controlled by an enable signal from the enable circuit 238, for turning the amplifier/buffer 104, including first OTA 202 and the second OTA 204, on and off.

Signal voltages applied to the inputs 214 and 216 of the first OTA 202 and the second OTA 204, respectively, are converted into currents by differential amplifiers and applied to the pair of FETs 504 at a current that may briefly but substantially exceed the FET quiescent current. However, this does not cause the source voltages to move very much: large sinking currents will be limited by the NFETs, large sourcing currents by the PFETs. The PFETs and NFETs effectively operate as bidirectional cascode devices, where the drain currents drive the output circuits. The FETs 504 can turn the output driver on and off very quickly to save power. The DC current (bp_c) offsets the output common mode range, centered at about 300mV, for example.

FIG. 6 is a schematic diagram of the first differential current mirror circuit 206, the second differential current mirror circuit 208, and the tapped resistor series 210, in accordance with an example of the present disclosure. In the output circuit, common mode currents sourced to nodes gp_n and gn_n, and sinking currents from nodes gp_p and gn_p, are effectively driving diode connected FETs, which keeps the common mode gain low. The nodes gp_n, gn_n, gp_p, and gn_p directly drive the gates of the output devices, forming the current mirror circuits 206 and 208, which set the quiescent operating point and also provide a modest gain. However, significantly higher impedances are seen by differential signals, resulting in considerably higher gain. The resistors in the current mirror circuits 206 and 208, in addition to a biasing function, have a high pass effect, boosting the high frequency gain and slew rate.

Unless specifically stated otherwise, it will be appreciated that terms such as “processing,” “computing,” “calculating,” and “determining” refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system.

The terms “circuit” or “circuitry” can include, for example, hardwired circuitry, programmable circuitry, such as computer processors comprising one or more individual instruction processing cores, state machine circuitry, and/or firmware that stores instructions executed by programmable circuitry. The circuitry can include a processor and/or controller configured to execute one or more instructions to perform one or more operations described herein. The instructions can be implemented as, for example, an application, software, firmware, etc., configured to cause the circuit or circuitry to perform any of the operations or functions described herein. Software can be implemented as a software package, code, instructions, instruction sets and/or data recorded on a computer-readable storage device. Software can be implemented to include any number of processes, and processes, in turn, can be implemented to include any number of threads, etc., in a hierarchical fashion. Firmware can be implemented as code, instructions or instruction sets and/or data that are hard-coded (e.g., nonvolatile) in memory devices. The circuit or circuitry can be implemented as part of a larger system, for example, an integrated circuit (IC), an application-specific integrated circuit (ASIC), a system-on-a-chip (SoC), desktop computers, laptop computers, tablet computers, servers, smartphones, etc. Other examples can be implemented as software executed by a programmable control device. In such cases, the terms “circuit” or “circuitry” are intended to include a combination of software and hardware such as a programmable control device or a processor capable of executing the software. As described herein, various examples can be implemented using hardware elements, software elements, or any combination thereof. Examples of hardware elements can include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, and/or chip sets.

Some embodiments can be described using the expression “coupled” and “connected” along with their derivatives. These terms are not intended as synonyms for each other. For example, some embodiments can be described using the terms “connected” and/or “coupled” to indicate that two or more elements are in direct physical or electrical contact with each other. The term “coupled,” however, can also mean that two or more elements are not in direct contact with each other, but still cooperate or interact with each other.

### Further Examples

The following examples pertain to further examples, from which numerous permutations and configurations will be apparent.

Example 1 provides an amplifier circuit comprising a first operational transconductance amplifier having a first input, a second input, a first output, and a second output; a second operational transconductance amplifier having a third input, a fourth input, a third output, and a fourth output; a first current mirror circuit coupled to the first output of the first operational transconductance amplifier and to the third output of the second operational transconductance amplifier; a second current mirror circuit coupled to the second output of the first operational transconductance amplifier and to the fourth output of the second operational transconductance amplifier; and a plurality of resistors coupled in series and coupled to the second input of the first operational transconductance amplifier and to the fourth input of the second operational transconductance amplifier, and further coupled to the first and second current mirrors; a first amplifier output coupled between the first and second current mirrors; and a second amplifier output coupled between the first and second current mirrors.

Example 2 includes the subject matter of Example 1, further comprising a current source circuit coupled to the plurality of resistors.

Example 3 includes the subject matter of Examples 1 or 2, wherein the first input and the third input are non-inverting inputs, and wherein the second input and the fourth input are inverting inputs.

Example 4 includes the subject matter of any one of Examples 1-3, wherein the first output and the third output are each sinking outputs.

Example 5 includes the subject matter of Example 4, wherein the second output and the fourth output are each sourcing outputs.

Example 6 includes the subject matter of any one of Examples 1-5, further comprising a first switch coupled between the first and second current mirrors and the first amplifier output; and a second switch operatively coupled between the first and second current mirrors and the second amplifier output.

Example 7 includes the subject matter of any one of Examples 1-6, further comprising an enable circuit coupled to the first operational transconductance amplifier, the second operational transconductance amplifier, the first current mirror circuit, and the second current mirror circuit, wherein the enable circuit is configured to isolate each of the first operational transconductance amplifier, the second operational transconductance amplifier, the first current mirror circuit, and the second current mirror circuit from a power supply.

Example 8 provides an amplifier circuit comprising a first operational transconductance amplifier and a second operational transconductance amplifier together configured to amplify an input signal; a first current mirror circuit and a second current mirror circuit together configured to generate a constant voltage while the input signal is absent; a plurality of resistors in series with a current source and configured to control an offset voltage; and a first amplifier output and a second amplifier output each coupled to the first operational transconductance amplifier, the second operational transconductance amplifier, the first current mirror circuit, and the second current mirror circuit, the first amplifier output and the second amplifier output configured to output the amplified input signal based on the offset voltage.

Example 9 includes the subject matter of Example 8, wherein the current source circuit is coupled between two of the plurality of resistors in series.

Example 10 includes the subject matter of Examples 8 or 9, wherein the first current mirror circuit is coupled to a sinking output of the first operational transconductance amplifier and a sinking output of the second operational transconductance amplifier.

Example 11 includes the subject matter of Example 10, wherein the second current mirror circuit is coupled to a sourcing output of the first operational transconductance amplifier and a sourcing output of the second operational transconductance amplifier.

Example 12 includes the subject matter of any one of Examples 8-11, further comprising a first switch coupled between the first and second current mirrors and the first amplifier output; and a second switch coupled between the first and second current mirrors and the second amplifier output.

Example 13 includes the subject matter of any one of Examples 8-12, further comprising an enable circuit configured to isolate each of the first operational transconductance amplifier, the second operational transconductance amplifier, the first current mirror circuit, and the second current mirror circuit from a power supply.

Example 14 provides an amplifier circuit comprising a first operational transconductance amplifier having a first input configured to receive an input voltage, a first output configured to produce a first output current, and a second output configured to produce a second output current; a second operational transconductance amplifier having a second input configured to receive the input voltage, a third output configured to produce a third output current, and a fourth output configured to produce a fourth output current; a first differential current mirror circuit having a fifth input configured to receive the first output current from the first operational transconductance amplifier, a sixth input configured to receive the third output current from the second operational transconductance amplifier, a fifth output configured to produce a fifth output current, and a sixth output configured to produce a sixth output current; a second differential current mirror circuit having a seventh input configured to receive the second output current from the first operational transconductance amplifier, a seventh input configured to receive the fourth output current from the second operational transconductance amplifier, a seventh output configured to produce a seventh output current, and an eighth output configured to produce an eighth output current; a plurality of resistors in series, a first resistor in the plurality of resistors having a first lead configured to receive the fifth output current from the first differential current mirror circuit and the seventh output current from the second differential current mirror circuit, and a second resistor in the plurality of resistors having a second lead configured to receive the sixth output current from the first differential current mirror circuit and the eighth output current from the second differential current mirror circuit; a first amplifier output coupled to the first differential current mirror circuit and the second differential current mirror circuit; and a second amplifier output coupled to the first differential current mirror circuit and the second differential current mirror circuit, the first amplifier output and the second amplifier output configured to produce an output voltage based on the input voltage.

Example 15 includes the subject matter of Example 14, further comprising a current source circuit coupled to the plurality of resistors in series.

Example 16 includes the subject matter of Example 15, wherein the current source circuit is coupled between two of the plurality of resistors in series.\

Example 17 includes the subject matter of any one of Example 14-16, wherein the first differential current mirror circuit is coupled to a sinking output of the first operational transconductance amplifier and a sinking output of the second operational transconductance amplifier.

Example 18 includes the subject matter of any one of Examples 14-17, wherein the second differential current mirror circuit is coupled to a sourcing output of the first operational transconductance amplifier and a sourcing output of the second operational transconductance amplifier.

Example 19 includes the subject matter of any one of Examples 14-18, further comprising a first switch coupled between the first and second current mirrors and the first amplifier output; and a second switch coupled between the first and second current mirrors and the second amplifier output.

Example 20 includes the subject matter of any one of Examples 14-19, further comprising an enable circuit coupled to the first operational transconductance amplifier, the second operational transconductance amplifier, the first current mirror circuit, and the second current mirror circuit, wherein the enable circuit is configured to isolate each of the first operational transconductance amplifier, the second operational transconductance amplifier, the first current mirror circuit, and the second current mirror circuit from a power supply.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. An amplifier circuit comprising:
a first operational transconductance amplifier having a first input, a second input, a first output, and a second output;
a second operational transconductance amplifier having a third input, a fourth input, a third output, and a fourth output;
a first current mirror circuit coupled to the first output of the first operational transconductance amplifier and to the third output of the second operational transconductance amplifier;
a second current mirror circuit coupled to the second output of the first operational transconductance amplifier and to the fourth output of the second operational transconductance amplifier; and
a plurality of resistors coupled in series and coupled to the second input of the first operational transconductance amplifier and to the fourth input of the second operational transconductance amplifier, and further coupled to the first and second current mirrors;
a first amplifier output coupled between the first and second current mirrors; and
a second amplifier output coupled between the first and second current mirrors.

2. The amplifier circuit of claim 1, further comprising a current source circuit coupled to the plurality of resistors.

3. The amplifier circuit of claim 1, wherein the first input and the third input are non-inverting inputs, and wherein the second input and the fourth input are inverting inputs.

4. The amplifier circuit of claim 1, wherein the first output and the third output are sinking outputs.

5. The amplifier circuit of claim 4, wherein the second output and the fourth output are sourcing outputs.

6. The amplifier circuit of claim 1, further comprising a first switch coupled between the first and second current mirrors and the first amplifier output; and a second switch operatively coupled between the first and second current mirrors and the second amplifier output.

7. The amplifier circuit of claim 1, further comprising an enable circuit coupled to the first operational transconductance amplifier, the second operational transconductance amplifier, the first current mirror circuit, and the second current mirror circuit, wherein the enable circuit isolates the first operational transconductance amplifier, the second operational transconductance amplifier, the first current mirror circuit, and the second current mirror circuit from a power supply.

8. An amplifier circuit comprising:
a first operational transconductance amplifier and a second operational transconductance amplifier together configured to amplify an input signal;
a first current mirror circuit and a second current mirror circuit together generating:
a constant voltage while the input signal is absent;
a plurality of resistors in series with a current source and configured to control an offset voltage; and
a first amplifier output and a second amplifier output each coupled to the first operational transconductance amplifier, the second operational transconductance amplifier, the first current mirror circuit, and the second current mirror circuit, the first amplifier output and the second amplifier output configured to output the amplified input signal based on the offset voltage.

9. The amplifier circuit of claim 8, wherein the current source is coupled between two of the plurality of resistors in series.

10. The amplifier circuit of claim 8, wherein the first current mirror circuit is coupled to a sinking output of the first operational transconductance amplifier and a sinking output of the second operational transconductance amplifier.

11. The amplifier circuit of claim 10, wherein the second current mirror circuit is coupled to a sourcing output of the first operational transconductance amplifier and a sourcing output of the second operational transconductance amplifier.

12. The amplifier circuit of claim 8, further comprising a first switch coupled between the first and second current mirrors and the first amplifier output; and a second switch coupled between the first and second current mirrors and the second amplifier output.

13. The amplifier circuit of claim 8, further comprising an enable circuit isolating each of the first operational transconductance amplifier, the second operational transconductance amplifier, the first current mirror circuit, and the second current mirror circuit from a power supply.

14. An amplifier circuit comprising:
a first operational transconductance amplifier having a first input configured to receive an input voltage, a first output configured to produce a first output current, and a second output configured to produce a second output current;
a second operational transconductance amplifier having a second input configured to receive the input voltage, a third output configured to produce a third output current, and a fourth output configured to produce a fourth output current;
a first differential current mirror circuit having a fifth input configured to receive the first output current from the first operational transconductance amplifier, a sixth input configured to receive the third output current from the second operational transconductance amplifier, a fifth output configured to produce a fifth output current, and a sixth output configured to produce a sixth output current;
a second differential current mirror circuit having a seventh input configured to receive the second output current from the first operational transconductance amplifier, a seventh input configured to receive the fourth output current from the second operational transconductance amplifier, a seventh output configured to produce a seventh output current, and an eighth output configured to produce an eighth output current;
a plurality of resistors in series, a first resistor in the plurality of resistors having a first lead configured to receive the fifth output current from the first differential current mirror circuit and the seventh output current from the second differential current mirror circuit, and a second resistor in the plurality of resistors having a second lead configured to receive the sixth output current from the first differential current mirror circuit and the eighth output current from the second differential current mirror circuit;
a first amplifier output coupled to the first differential current mirror circuit and the second differential current mirror circuit; and
a second amplifier output coupled to the first differential current mirror circuit and the second differential current mirror circuit, the first amplifier output and the second amplifier output configured to produce an output voltage based on the input voltage.

15. The amplifier circuit of claim 14, further comprising a current source circuit coupled to the plurality of resistors in series.

16. The amplifier circuit of claim 15, wherein the current source circuit is coupled between two of the plurality of resistors in series.

17. The amplifier circuit of claim 14, wherein the first differential current mirror circuit is coupled to a sinking output of the first operational transconductance amplifier and a sinking output of the second operational transconductance amplifier.

18. The amplifier circuit of claim 14, wherein the second differential current mirror circuit is coupled to a sourcing output of the first operational transconductance amplifier and a sourcing output of the second operational transconductance amplifier.

19. The amplifier circuit of claim 14, further comprising a first switch coupled between the first and second current mirrors and the first amplifier output; and a second switch coupled between the first and second current mirrors and the second amplifier output.

20. The amplifier circuit of claim 14, further comprising an enable circuit coupled to the first operational transconductance amplifier, the second operational transconductance amplifier, the first differential current mirror circuit, and the second differential current mirror circuit, wherein the enable circuit isolates each of the first operational transconductance amplifier, the second operational transconductance amplifier, the first current mirror circuit, and the second current mirror circuit from a power supply.
